(19) United States
(12) Patent Application Publication
(10) Pub. No.: US 2025/0094676 A1
(43) Pub. Date: Mar. 20, 2025

(54) GENERATING SUGGESTED COMMUNICATIONS BY SIMULATING INTERACTIONS USING LANGUAGE MODEL NEURAL NETWORKS

(71) Applicant: DeepMind Technologies Limited, London (GB)

(72) Inventors: Ian Michael Gemp, London (GB); Yoram Bachrach, London (GB)

(21) Appl. No.: 18/892,217

(22) Filed: Sep. 20, 2024

Related U.S. Application Data
(60) Provisional application No. 63/584,151, filed on Sep. 20, 2023.

(51) Int. Cl. G06F 30/27

(52) U.S. Cl. CPC G06F 30/27

(57) ABSTRACT

Methods, systems, and apparatus, including computer programs encoded on computer storage media, for generating suggested communications during a multi-agent interaction using a language model neural network.

### CROSS-REFERENCE TO RELATED APPLICATION

This application claims priority to U.S. Provisional Application No. 63/584,151, filed on Sep. 20, 2023. The disclosure of the prior application is considered part of and is incorporated by reference in the disclosure of this application.

### BACKGROUND

This specification relates to processing data using machine learning models.

As one example, neural networks are machine learning models that employ one or more layers of nonlinear units to predict an output for a received input. Some neural networks include one or more hidden layers in addition to an output layer. The output of each hidden layer is used as input to another layer in the network, e.g., the next hidden layer or the output layer. Each layer of the network generates an output from a received input in accordance with current values of a respective set of weights.

### SUMMARY

This specification describes a system implemented as computer programs on one or more computers in one or more locations that generates suggestions for a given actor in a multi-actor interaction by simulating the interaction using a language model neural network.

Particular embodiments of the subject matter described in this specification can be implemented so as to realize one or more of the following advantages.

This specification describes techniques for generating suggested communications for actors in a multi-actor interaction. As one example, the multi-actor interaction can be a communication session in which a user exchanges natural language communications with one or more other actors, e.g., other users, software agents, or both. Thus, in this example, the system can generate suggested natural language communications, e.g., e-mail messages, text messages, chat messages, and so on, to be sent by the user to the one or more other agents.

Some existing techniques, e.g., auto-completion techniques or next turn prediction techniques, attempt to predict the next communication in the interaction given the previous communications and, in some cases, previous interactions engaged in by the user.

However, these approaches fail to consider that different interactions can have different objectives, which would make different suggestions more appropriate than others, even given the same previous communications. Moreover, these approaches generate short-term predictions that fail to consider the longer-term impact on a given interaction of the next communication in the interaction, e.g., the impact of a given communication on the communications that will be received from other agents.

This specification, on the other hand, generates suggested communications using an entirely different paradigm. In particular, this specification generates suggestions by evaluating multiple different parameterizations of a set of context variables for the communications, both for the “first” actor for which suggestions are being generated and for the other actors in the interaction, using a language model neural network, and then selecting the parameterization that will result in the objective(s) for the interaction being satisfied. To do so, the system can generate simulations of the interaction using the language model neural network, and then score each of those simulations to determine the degree to which the simulated interaction satisfied the objective(s) for the interaction.

As a result, the system leverages the capabilities of the language model neural network to effectively “model” the effect of different parameterizations of the context variables on the remainder of the interaction. This results in suggested communications that are more effective and more tailored to the current interaction, improving the user experience.

Moreover, by performing simulations of the current interaction at different time steps within the current interaction, the system can effectively adjust the strategy for generating suggested communications as the current interaction progresses, further improving the relevance and utility of the generated suggested and further improving the user experience.

The details of one or more embodiments of the subject matter of this specification are set forth in the accompanying drawings and the description below. Other features, aspects, and advantages of the subject matter will become apparent from the description and the drawings.

### BRIEF DESCRIPTION OF THE DRAWINGS

FIG. 1 is a diagram of an example neural network system.

FIG. 2 is a flow diagram of an example process for generating a suggested communication using a language model neural network.

FIG. 3 is a flow diagram of an example process for generating a simulation for a pair of strategies.

FIG. 4 is a flow diagram of an example process for generating a score for a simulation.

FIG. 5 is a flow diagram of an example process generating a suggested communication for a user during a communication session.

FIG. 6 shows an example of generating a suggested communication using the language model neural network.

Like reference numbers and designations in the various drawings indicate like elements.

### DETAILED DESCRIPTION

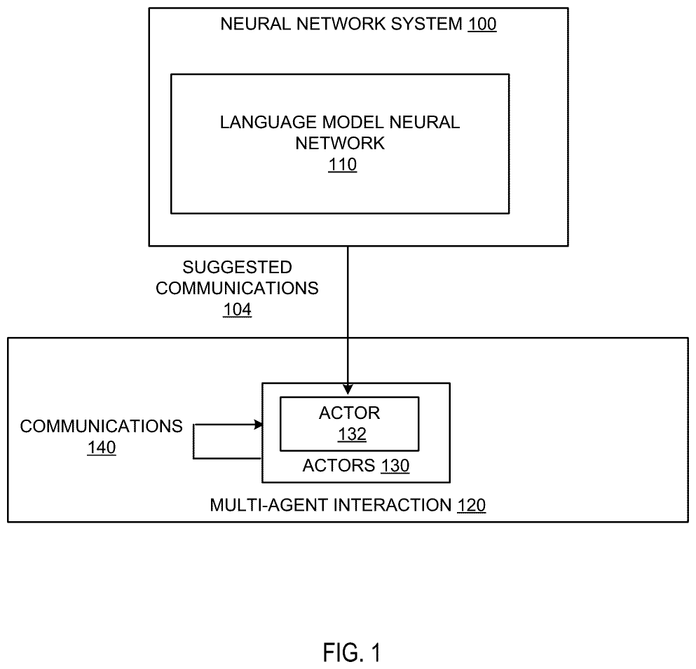

FIG. 1 is a diagram of an example neural network system 100. The neural network system 100 is an example of a system implemented as computer programs on one or more computers in one or more locations, in which the systems, components, and techniques described below can be implemented.

The system 100 is a system that generates suggested communications 104 for a first actor 132 in a multi-actor interaction 120 by simulating the interaction using a language model neural network 110.

The language model neural network 110 is a neural network that is configured to process an input to generate an output that includes a probability distribution over a set of text tokens in a vocabulary of text tokens, with the probability for each token representing the likelihood that the text token immediately follows the input. The tokens in the vocabulary can include text tokens, e.g., characters, sub words, word pieces, and so on, and, optionally, tokens representing other types of data, e.g., audio, images, video, or other sensor data.

For example, the language model neural network can be an auto-regressive language model neural network.

The language model neural network is referred to as an auto-regressive neural network because the neural network auto-regressively generates an output sequence of tokens by generating each particular token in the output sequence conditioned on a current input sequence that includes any tokens that precede the particular text token in the output sequence, i.e., the tokens that have for already been generated for any previous positions in the output sequence that precede the particular position of the particular token, and a context input that provides context for the output sequence (a “context sequence”).

For example, the current input sequence when generating a token at any given position in the output sequence can include the context sequence and the tokens at any preceding positions that precede the given position in the output sequence. As a particular example, the current input sequence can include the context sequence followed by the tokens at any preceding positions that precede the given position in the output sequence. Optionally, the context and the current output sequence can be separated by one or more predetermined tokens within the current input sequence.

More specifically, to generate a particular token at a particular position within a candidate output sequence, the neural network can process the current input sequence to generate a score distribution, e.g., a probability distribution, that assigns a respective score, e.g., a respective probability, to each text token in the vocabulary of text tokens. The neural network can then select, as the particular token, a text token from the vocabulary using the score distribution. For example, the neural network can greedily select the highest-scoring token or can sample, e.g., using nucleus sampling or another sampling technique, a token from the distribution.

As a particular example, the language model neural network can be an auto-regressive Transformer-based neural network that includes (i) a plurality of attention blocks that each apply a self-attention operation and (ii) an output subnetwork that processes an output of the last attention block to generate the score distribution.

The neural network can have any of a variety of Transformer-based neural network architectures. Examples of such architectures include those described in J. Hoffmann, S. Borgeaud, A. Mensch, E. Buchatskaya, T. Cai, E. Rutherford, D. d. L. Casas, L. A. Hendricks, J. Welbl, A. Clark, et al., Training compute-optimal large language models, arXiv preprint arXiv:2203.15556, 2022; J. W. Rae, S. Borgeaud, T. Cai, K. Millican, J. Hoffmann, H. F. Song, J. Aslanides, S. Henderson, R. Ring, S. Young, E. Rutherford, T. Hennigan, J. Menick, A. Cassirer, R. Powell, G. van den Driessche, L. A. Hendricks, M. Rauh, P. Huang, A. Glaese, J. Welbl, S. Dathathri, S. Huang, J. Uesato, J. Mellor, I. Higgins, A. Creswell, N. McAleese, A. Wu, E. Elsen, S. M. Jayakumar, E. Buchatskaya, D. Budden, E. Sutherland, K. Simonyan, M. Paganini, L. Sifre, L. Martens, X. L. Li, A. Kuncoro, A. Nematzadeh, E. Gribovskaya, D. Donato, A. Lazaridou, A. Mensch, J. Lespiau, M. Tsimpoukelli, N. Grigorev, D. Fritz, T. Sottiaux, M. Pajarskas, T. Pohlen, Z. Gong, D. Toyama, C. de Masson d'Autume, Y. Li, T. Terzi, V. Mikulik, I. Babuschkin, A. Clark, D. de Las Casas, A. Guy, C. Jones, J. Bradbury, M. Johnson, B. A. Hechtman, L. Weidinger, I. Gabriel, W. S. Isaac, E. Lockhart, S. Osindero, L. Rimell, C. Dyer, O. Vinyals, K. Ayoub, J. Stanway, L. Bennett, D. Hassabis, K. Kavukcuoglu, and G. Irving. Scaling language models: Methods, analysis & insights from training gopher. CoRR, abs/2112.11446, 2021; Colin Raffel, Noam Shazeer, Adam Roberts, Katherine Lee, Sharan Narang, Michael Matena, Yanqi Zhou, Wei Li, and Peter J Liu. Exploring the limits of transfer learning with a unified text-to-text transformer. arXiv preprint arXiv:1910.10683, 2019; Daniel Adiwardana, Minh-Thang Luong, David R. So, Jamie Hall, Noah Fiedel, Romal Thoppilan, Zi Yang, Apoorv Kulshreshtha, Gaurav Nemade, Yifeng Lu, and Quoc V. Le. Towards a human-like open-domain chatbot. CoRR, abs/2001.09977, 2020; and Tom B Brown, Benjamin Mann, Nick Ryder, Melanie Subbiah, Jared Kaplan, Prafulla Dhariwal, Arvind Neelakantan, Pranav Shyam, Girish Sastry, Amanda Askell, et al., Language models are few-shot learners. arXiv preprint arXiv:2005.14165, 2020.

Generally, however, the Transformer-based neural network includes a sequence of attention blocks, and, during the processing of a given input sequence, each attention block in the sequence receives a respective input hidden state for each input token in the given input sequence. The attention block then updates at least the hidden state for the last token in given input sequence at least in part by applying self-attention to generate a respective output hidden state for the last token. The input hidden states for the first attention block are embeddings of the input tokens in the input sequence and the input hidden states for each subsequent attention block are the output hidden states generated by the preceding attention block.

In this example, the output subnetwork processes the output hidden state generated by the last attention block in the sequence for the last input token in the input sequence to generate the score distribution.

Generally, prior to using the neural network 100, the system 100 or another training system pre-trains the language model neural network 110 on a language modeling task, e.g., a task that requires predicting, given a current sequence of text tokens, the next token that follows the current sequence in the training data. As a particular example, the language model neural network can be pre-trained on a maximum-likelihood objective on a large dataset of text, e.g., text that is publicly available from the Internet or another text corpus. In some cases, the system 100 or another training system then further trains the language model neural network 110, e.g., on one or more objectives that include supervised fine-tuning, reinforcement learning, instruction-tuning, and so on.

In some implementations, the language model neural network 110 is then fine-tuned to perform the tasks described below. In other implementations, the language model neural network 110 is not further trained and can be caused to generate appropriate outputs, e.g., by including, in any given input to the neural network 110, a natural language instruction, a few-shot prompt, or a combination of the two.

As described above, the system 100 uses the language model neural network 110 to generate suggested communications for a first actor 132 that is one of multiple actors 130 in a multi-actor interaction 120.

The multi-actor interaction 120 can be any appropriate interaction where multiple actors 130 transmit communications 140 amongst one another.

For example, the multi-actor interaction 120 can be a communication session where multiple actors 130 exchange electronic messages, e.g., e-mails, chats, SMS messages, MMS messages and so on. In this example, the communications 140 will generally be natural language communications that all of or part of an electronic message.

In this example, the “first actor” 132 that requires suggestions can be a user of a user device, e.g., a “first user,” and the system 100 can provide the suggested communication for presentation to the first user in a user interface of the user device. The other actors can include other users, automated agents, or a combination of both.

In this example, the first user can specify one or more objectives for the interaction. For example, the first user can submit a natural language input specifying the objectives for the interaction. As another example, the first user can submit an input selecting one or more predetermined objectives for the interaction from a set of possible objectives or can complete a form to specify the objectives.

As another example, the system 100 can process one or more initial communications from the interaction using the language model neural network 110 (or another model) to generate one or more candidate objectives for the interaction and the user 132 can submit an input selecting one or more of the candidate objectives as the final objective(s) for the interaction.

As yet another example, the system 100 can automatically identify the objectives for the interaction based on a context for the interaction and, optionally, the one or more initial communications from the interaction. For example, the system 100 can identify the objective based on the software application or web site used to transmit the communications for the interaction and the initial communication(s), e.g., when the interaction involves a web site that makes travel bookings and the initial communication identifies a range of dates, the system can identify the objective of the interaction being to make a travel booking during the specified range of dates.

The objectives can be based on, e.g., the sentiment of the communications of the first user, the other agents, or both. That is, one or more of the objectives can specify a target sentiment for the communications of the first user, the other agent(s), or both during the interaction.

As another example, the objectives include one or more objectives that are based on a goal of the first user for the interaction. For example, objectives can include resolving an issue that the first user is having, taking a specified action, or achieving another type of goal of the first user for the interaction.

The communication session can be any appropriate communication session on any appropriate topic, e.g., a customer support session, a negotiation, a contest, a scheduling or logistics session, a collaboration session, and so on.

In another example, the multi-agent interaction 120 can be a communication session between mechanical, electronic, or electro-mechanical agents, e.g., robots, autonomous vehicles, or other agents. In this example, the communications can be natural language communications, computer code segments, or communications in a domain-specific language that can be parsed by the agents. Examples of such communications can be communications for allocating or distributing resources, scheduling or logistics, and so on.

In this example, the “first actor” 132 that requires suggestions can be one of the agents.

In this example, a user of the system 100 can specify one or more objectives for the interaction that relate to the first user. For example, the objectives can be based on, e.g., the amount of resources allocated to the first agent as a result of the interaction, the navigation time to a destination of the first agent as a result of the interaction, and so on.

More specifically, the system 100 uses the language model neural network 110 to generate a respective suggested communication for the first actor 132 at each of multiple time steps during the interaction 120.

Generating a suggested communication is described in more detail below.

When the first actor 132 is a user, the user can then determine whether to submit the suggested communication as a communication to one or more of the other actors 130. When the first actor 132 is an agent, the system 100 can automatically submit the communication as a communication of the agent to one or more of the other actors 130 or a control system can determine whether to submit the suggested communication to one or more of the other actors 130.

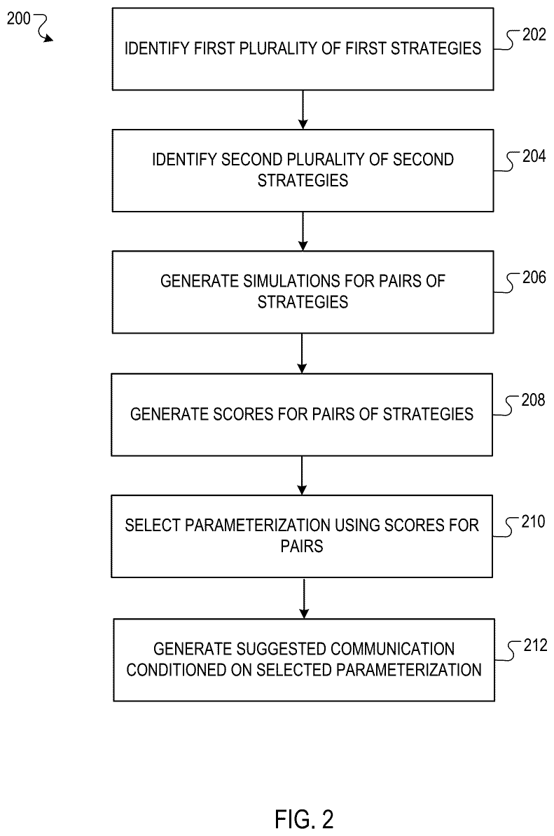

FIG. 2 is a flow diagram of an example process 200 for generating a suggested communication at a given time step during an interaction between a plurality of actors. For convenience, the process 200 will be described as being performed by a system of one or more computers located in one or more locations. For example, a neural network system, e.g., the neural network system 100 depicted in FIG. 1, appropriately programmed in accordance with this specification, can perform the process 200.

The system can perform the process 200 at various time points during an interaction. For example, the system can perform the process 200 each time a first actor of the plurality of actors requests a suggestion from the system. For example, a user can select a user interface element that requests a suggested response communication when viewing the most-recent communication in the interaction.

The system identifies a first plurality of first strategies for selecting between first parameterizations for communications for the first actor (step 202).

Generally, each first parameterization parametrizes a set of one or more context variables for the communications of the first actor during the interaction.

That is, each first parameterization includes a respective value for each of a set of one or more context variables that each impact how the first actor communicates during the communication.

For example, one or more of the context variables in the set can define a communication style for the communications of the first actor. Examples of such context variables include communication tone, sentiment, argument style, writing style, use of literary techniques, and so on.

As another example, one or more of the context variables in the set can define a set of information that is available as context to the first actor during the interaction. That is, each of these context variables can determine how much outside information is available to the first user (outside of the communications exchanged during the interaction) during the communication.

In some cases, the possible values for each context variable are a discrete set of possible values, i.e., the context variable has a fixed, discrete set of possible values. For example, for the communication tone context variable, the possible values can be a fixed set that includes some or all of the following: formal, informal, optimistic, cooperative, friendly, funny, satirical, assertive, cheerful, angry, and so on.

In other cases, the possible values for one or more of the context variables are continuous values. For example, for the communication context tone variable, the possible values can be selected from a continuous range between zero and one, where zero represents an informal tone and one represents a formal tone.

In some cases, all of the first strategies assign the same parametrization for all communications during the interaction. That is, each first strategy can assign the same values for the context variables for all of the communications of the first agent during the entire interaction.

In some other cases, one or more of the first strategies assign different parameterizations to different communications, e.g., alternate between different parameterizations or cycle through a set of three or more parameterizations.

The system also identifies a second plurality of second strategies for selecting between second parameterizations for communications for a second actor of the plurality of actors for the interaction (step 204).

Each second parameterization parametrizes a set of context variables for the communications of the second actor during the interaction.

The strategies, sets of context variables, and the parameterizations can be the same for the first and second actors or can differ between the first and second actors.

Generally, the sets of context variables and, in some cases, the parameterizations for the actors can be received as input by the system.

In some implementations, the system can generate or augment the possible values for a given one of the context variables using a language model neural network, e.g., the language model neural network described above or a different language model neural network, e.g., a smaller, more computationally efficient language model neural network.

For example, the system can receive an initial input specifying a context variable and, optionally, one or more possible values for the context variable and can then process an input specifying the context variable and, when available, the one or more possible values using the language model neural network to generate one or more additional possible values. That is, given an input identifying a context variable, the system can use the neural network to generate suggested possible values for the context variable.

In some implementations, the system can generate the strategies for a given actor by selecting all possible parameterizations of the set of context variables, by randomly selecting a fixed number of parametrizations from the set of possible parameterizations, or by using some other selection scheme.

In some other implementations, in addition to specifying the context variables and the parameterizations, the user input can also identify the strategies for the first user, the second user, or both.

For each of a plurality of pairs that each include a respective first strategy and a respective second strategy, the system generates, using the language model neural network, one or more simulations of the interaction given that the first actor communicates in accordance with the first strategy and the second actor communicates in accordance with the second strategy (step 206).

For example, the system can select all possible pairs of first and second strategies or can randomly select a subset of the possible pairs of first and second strategies, e.g., randomly select a number of pairs that can be simulated within a latency budget for generating the selected communication.

In some cases, the system generates a single simulation for each pair. In some other cases, because the language model neural network can generate different output sequences for the same input sequence as described above, the system can generate multiple distinct simulations for the same pair.

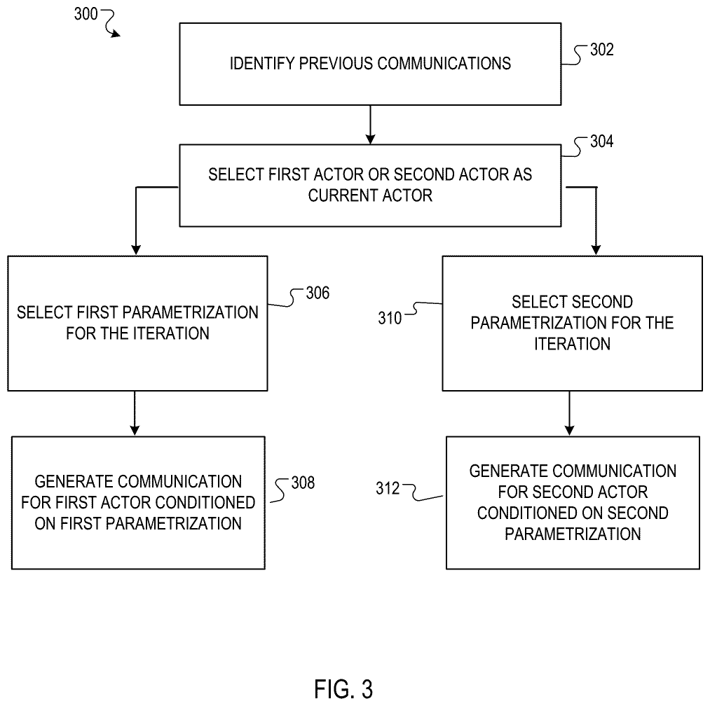

Generating a simulation using the language model neural network is described in more detail below with reference to FIG. 3.

The system then determines, from the one or more simulations, a score for the pair that indicates a degree to which the first actor communicating in accordance with the first strategy and the second actor communicating in accordance with the second strategy satisfies one or more objectives for the interaction (step 208).

For example, as described above the objective(s) can be received as input by the system and can be the objective to be achieved by the first actor.

Determining a score for a pair of strategies is described in more detail below.

When there is more than one simulation, the system can determine a respective simulation score for each simulation and then combine, e.g., average or sum or otherwise combine, the simulation scores to generate the final score for the pair.

The system then selects, using the scores for the plurality of pairs, a first parametrization for the first actor (step 210).

For example, the system can generate a representation of the interaction that includes the scores for the pairs and then apply a game theory solver to the representation to identify the optimal first parametrization for the first actor. Examples of such a representation include a payoff matrix, a payoff tensor, and a game tree.

Examples of game theory solvers that can be used include normal-form game (NFG) solvers, extensive-form game (EFG) solvers, multi-agent reinforcement learning (MARL) solvers. One example of a MARL solver is the Policy Space Response Oracles (PSRO) solver.

Thus, applying the game theory solver results in identifying, based on the results of the simulations, the first parameterization that is most likely to result in the objective(s) for the interaction being satisfied if used to generate the communication for the first agent at the current step in the interaction.

The system then generates, by processing an input that conditions the language model neural network on the selected first parameterization, a suggested communication for the first actor (step 212). That is, the system generates, given the context of the interaction up to the given time step, a suggested communication that is characterized by the first parameterization.

More specifically, the system can process an input that identifies the selected parameterization and that includes the context of the interaction up to the given time step and an instruction to generate a suggested communication that is parameterized by the selected parameterization given the context using the language model neural network to generate the suggested communication.

The input can optionally also include additional information.

For example, the input can include information characterizing the first agent or characterizing the objective of the first agent for the interaction. This information can include “private” information that is not available from the messages in the interaction so far.

For example, when the first agent is attempting to coordinate a time for a meeting, the first agent may not have yet communicated the first agent's preferred meeting times during the interaction. As another example, when the first agent is attempting to negotiate a price for a service or a good, the first agent may not have communicated the first user's target price for the service for the good.

The system can then provide the suggested communication, e.g., to a control system of the first actor or for presentation the first actor.

FIG. 3 is a flow diagram of an example process 300 for generating a simulation of an interaction for a pair of strategies using the language model neural network. For convenience, the process 300 will be described as being performed by a system of one or more computers located in one or more locations. For example, a neural network system, e.g., the neural network system 100 depicted in FIG. 1, appropriately programmed in accordance with this specification, can perform the process 300.

For example, given a pair that include a respective first strategy and a respective second strategy, the system can perform the process 300 to generate a simulation of the interaction given that the first actor communicates in accordance with the first strategy and the second actor communicates in accordance with the second strategy.

In particular, the system can perform the process 300 at each of multiple iterations in order to generate a respective communication for each of the iterations. The communications across the iterations then serve as the simulation of the interaction starting from the current point in the interaction.

The system identifies previous communications between the first actor and the second actor during the simulation, i.e., communications that have been generated at any previous iterations during generation of the simulation (step 302). Optionally, when the simulation is being generated after the interaction has already begun, the system can also identify previous actual communications that have been generated during the interaction prior to the simulation beginning to be generated.

The system selects the first actor or the second actor as a current actor for the iteration (step 304). Generally, the system selects the first actor and the second actor according to a model of how actors interact during the interaction being simulated.

For example, the model can indicate that the two actors alternate communications during the interaction. In this example, the system can select the first actor if the second actor generated the most-recent identified communication and can select the second actor if the second first generated the most-recent identified communication.

As another example, the model can indicate that each communication is sent by the first actor unless the most recent communication by the first actor satisfies certain criteria, e.g., includes a request for a response from the second actor. In this example, the system can select the second actor only if the most recent communication is from the first actor and satisfies the certain criteria.

As yet another example, the model can indicate that at any given iteration, the first actor generates the communication with probability p and the second actor generates the communication with probability 1−p. In this example, the system selects the first actor with probability p and the second actor with probability 1−p.

When the first actor is selected as the current actor, the system selects a first parametrization for the iteration in accordance with the first strategy (step 306). That is, the system applies the first strategy to the identified communications to determine the first parameterization.

The system then processes, using the language model neural network, (i) an input that conditions the language model neural network on the selected first parameterization and (ii) at least some of the previous communications during the simulation to generate a communication for the first actor (step 308). For example, the input can include a description of the selected first parametrization and an instruction to generate a communication that is parameterized by the selected first parametrization given the context provided by the previous communications. As described above, the input to the language model neural network can also optionally include actual previous communications from earlier in the actual interaction. Additionally, as described above, the input can also include “private” information characterizing the first actor or the state of the interaction.

When the second actor is selected as the current actor, the system selects a second parametrization for the iteration in accordance with the second strategy (step 310). That is, the system applies the second strategy to the identified communications to determine the second parameterization.

The system then processes, using the language model neural network, (i) an input that conditions the language model neural network on the selected second parameterization and (ii) at least some of the previous communications during the simulation to generate a communication for the second actor (step 312). For example, the input can include a description of the selected second parametrization and an instruction to generate a communication that is parameterized by the selected second parametrization given the context provided by the previous communications. As described above, the input to the language model neural network can also optionally include actual previous communications from earlier in the actual interaction. The system may not have access to “private” information for the second actor. In this, case the system can either omit this information from the input, include an indication that the information is not available, or can randomly sample the information from a set of plausible characterizations.

Thus, by repeatedly performing iterations of the process 300, the system generates a simulation that includes a respective communication from one of the actors at each of multiple iterations.

The system continues to perform iterations of the process 300 until a termination criterion is satisfied.

For example, the system can determine that the termination criterion is satisfied when a pre-determined number of iterations have been performed.

As another example, the system can determine that the termination criterion is satisfied when the communication generated at the iteration satisfies a specified pattern for a communication that signifies the end of the interaction.

As yet another example, at each iteration, the system can process, using the language model neural network, an input that includes the communication generated at the iteration and a prompt that asks the language model neural network whether the interaction has ended. The system can then determine that the termination criterion is satisfied when the output of the language model neural network indicates that the interaction has ended. For example, the input can also include data characterizing the objective(s) for the interaction and can ask if the objectives have been satisfied. As another example, if the input also includes data characterizing the objective(s), the input can also ask if the objective(s) are not able to be achieved given the current state of the interaction.

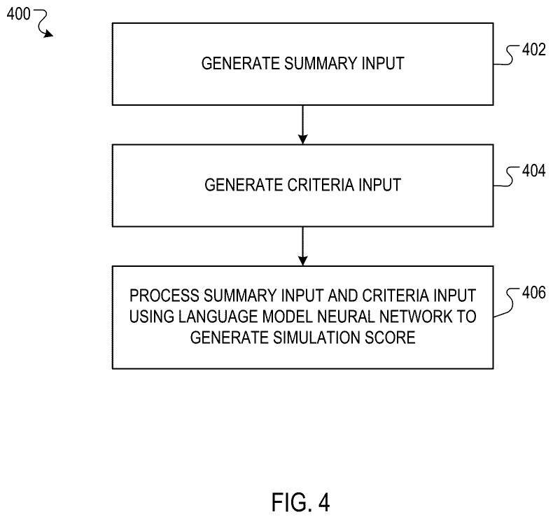

FIG. 4 is a flow diagram of an example process 400 for determining a score for a simulation of an interaction for a pair of strategies using the language model neural network. For convenience, the process 400 will be described as being performed by a system of one or more computers located in one or more locations. For example, a neural network system, e.g., the neural network system 100 depicted in FIG. 1, appropriately programmed in accordance with this specification, can perform the process 400.

The system generates a summary input from one or more of the communications generated during the simulation (step 402).

For example, the summary input can include all of the communications generated during the simulation. As another example, the summary input can include less than all of the communications generated during the simulation, e.g., every n-th communication during the simulation, where n is an integer greater than one, or the communications that the k last iterations during the simulation, where k is an integer greater than or equal to one.

As another example, the summary input can be an extractive summary of the communication. To generate the extractive summary, the system can process the communications generated during the simulation and an appropriate prompt using a second language model neural network.

The “second” language model neural network can be the same as the language model neural network described above or a different, smaller, language model neural network.

The system generates a criteria input characterizing the objective for the interaction (step 404). For example, the criteria input can be a natural language description of the objective for the interaction.

The system processes the summary input and the criteria input using the second language model neural network to generate an output that defines a simulation score for the simulation that indicates a degree to which the simulation satisfies the one or more criteria (step 406).

For example, the system can process the summary input, the criteria input, and an instruction to score the interaction defined by the summary input given the criteria described in the criteria input using the second language model neural network to cause the second language model neural network to generate the summary score.

As one example, the score can be the probability, the log probability, the logit, or other likelihood assigned by the second language model neural network to a predetermined response phrase, e.g., the phrase “Yes” or the phrase “NO.”

For example, in this example, the input to the second language model neural network can include a query that asks the second language model neural network whether the interaction summarized by the summary input satisfies the criteria. For example, the input can be of the form “Given this summary of an interaction [summary input], does the interaction satisfy these criteria: [criteria input]?” As another example, the input can include k examples of the form “Summary: [example summary input]; Criteria: [example criteria input]; does the summary satisfy the criteria?[yes/no],” where k is greater than or equal to one, followed by “Summary: [summary input]; Criteria: [criteria input]; does the summary satisfy the criteria?.”

As another example, the score can be directly regressed as one or more output tokens by the second language model neural network in response to processing the input. That is, the instruction can cause the language model neural network to directly output a score by processing the input.

For example, in this example, the input to the second language model neural network can include a query that asks the second language model neural network to score the degree to which the summary input satisfies the criteria specified by the criteria input. For example, the input can be of the form “Given this summary of an interaction [summary input] and the following criteria: [criteria input], please output a score between 0 and 1 that rates the degree to which the criteria are satisfied.” As another example, the input can include k examples of the form “Summary: [example summary input]; Criteria: [example criteria input]; criteria satisfaction score: [example score],” where k is greater than or equal to one, followed by “Summary: [summary input]; Criteria: [criteria input]; criteria satisfaction score:.”

Alternatively, rather than performing steps 404 and 406, the system can receive data specifying a set of heuristics to be applied to the summary input, e.g., the extractive summary as generated by the language model neural network or the combination of one or more of the communications. The system can then apply the set of heuristics to the summary input to generate the simulation score.

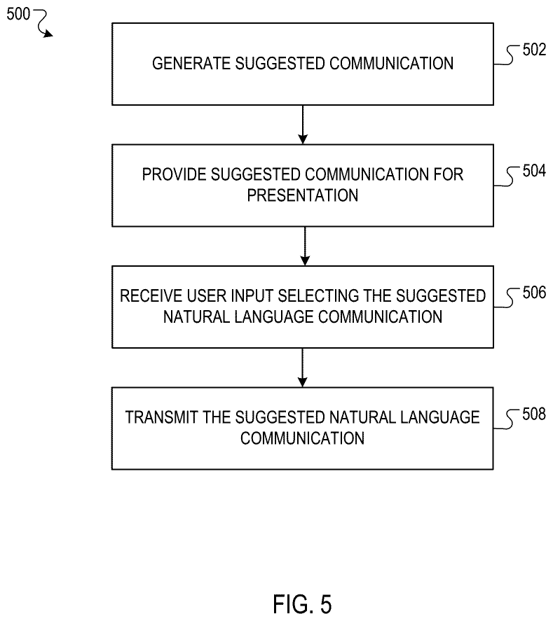

FIG. 5 is a flow diagram of an example process 500 for generating a suggested communication for a user during an interaction with another agent. For convenience, the process 400 will be described as being performed by a system of one or more computers located in one or more locations. For example, a neural network system, e.g., the neural network system 100 depicted in FIG. 1, appropriately programmed in accordance with this specification, can perform the process 500.

For example, the system can perform the process 500 during an interaction in which a user of a user device is participating in an interaction, e.g., a communication session, with another agent, e.g., another user of another user device or a software agent.

The communication session can be any appropriate communication session on any appropriate topic, e.g., a customer support session, a negotiation, a contest, a scheduling or logistics session, a collaboration session, and so on.

The communication session can be carried out through any appropriate software application, e.g., as part of an e-mail exchange, as part of an online chat, or as part of a text messaging exchange.

The system generates a suggested communication for the first user (step 502). For example, the system can generate the suggested communication for the first user as described above and using the language model neural network.

As a particular example, the system can have a received a request for a suggested communication from the user given the existing communications in the session and the context for the session. The context for the session generally specifies the one or more objectives for the session and, optionally, additional information about the session, e.g., information about the other agent in the session.

For example, consider an email conversation between Bob (tenant) and Alice (landlord). The system can generate the suggested communication given an initial email from Alice to Bob stating that she will have to increase rent:
Email from Alice to Bob:
############################
Hi Bob,
I hope you are well.

I understand you have been a long time tenant with me, so I hate to increase rent, but as you know inflation has increased by 6 percent recently. In order to stay solvent I will need to increase your rent by 6 percent as well. I hope you understand my thinking. How do you feel about this? Would you like to continue renting from me?
Best,
Alice
   As part of generating a suggested communication, the system could, e.g., iterate through the following email communications as part of one simulation:
Email from Bob to Alice:
############################
Hi Alice,
Thanks for your email.

I appreciate your candor and I understand your position. I'm in a tough spot because I have fixed income, and this is a lot of money for me. I also understand you have your own business expenses. I don't want to put you in a tough spot either.
Is there anything we can do to come to a compromise?
Best,
Bob
############################
Email from Alice to Bob:
############################
Hi Bob,
Thanks for sharing your thoughts. How about an increase of $300?
Best,
Alice

The system could also iterate through the following email communications as part of another simulation:
Email from Bob to Alice:
############################
Hi Alice,
Thank you for your kind words.

I have been here a long time and have been a good tenant. I was wondering if you would be willing to continue my lease at the current rate. If you will, I would be willing to sign a 5 year lease.
Best,
Bob
############################
Email from Alice to Bob:
############################
Hi Bob,
Thanks for sharing your thoughts. That sounds good, I will send you the lease
paperwork to sign.
Best,
Alice

After generating each simulation, the system can score the simulations as described above. For example, if Bob's objectives are to minimize the rent increase and to maintain a friendly relationship with Alice, the system can measure the rent increase, if any, in each simulation and perform a sentiment analysis on Alice's measure to generate a sentiment score and a rent increase score and then combine the scores to generate the final simulation score for the simulation.

The system can then apply a game theory solver to the simulation scores for the pairs of strategies to determine a final strategy and generate the selected communication in accordance with the final strategy.

The system provides the suggested communication for presentation to the first user in a user interface of the user device (step 504).

The system receives a user input selecting the suggested natural language communication (step 506). For example, the user may have selected a user interface element in the user interface indicating that the suggested communication is acceptable.

In response, the system transmits the suggested natural language communication to the second actor, e.g., over a data communication network (step 508).

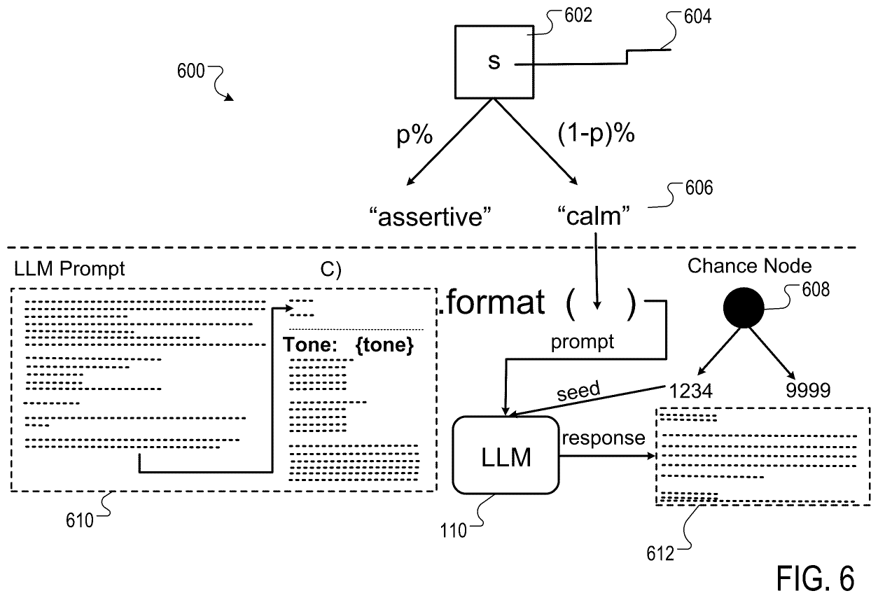

FIG. 6 shows an example 600 of generating a suggested communication using the language model neural network (“LLM”) 110. In the example 600, the interaction is a negotiation for trading fruit between “Sarah” and “Sophia” by way of email communications.

In the example 600, the set of context variables includes a single context variable “tone” that specifies the tone of a natural language communication. The possible values for the tone are “assertive” and “calm.”

In the example 600, the strategy samples 602 the value “assertive” with a probability p and the probability “calm” with probability 1−p. For example, these probabilities can be fixed or can be predicted with a learned model based on a current state s 604 of the interaction as of the time at which this suggestion communication is being generated. That is, the learned model can process the state 604 of the interaction, e.g., the communications already generated in the interaction or a summary of the interaction as described above, using the learned model to generate the probabilities p and 1−p. For example, the learned model can have been trained using reinforcement learning on a set of training interactions or using supervised learning using a set of training interactions that achieved the objective with each communication being labeled with the corresponding values of the context variables that were used to generate the communication.

In the example 600, the system selects the value “calm” 606 for the context variable.

To introduce stochasticity into the generation, the system also samples, using what is referred to in the example 600 as a “chance node,” 608 a seed for the generation of the suggested communication.

The system then processes a prompt 610 that identifies the context for the suggested communication and the selected value for the seed using the language model neural network 110 to generate a suggested communication 612 for Sophia that has a “calm” tone but that is responsive to the earlier communications in the interaction.

In the example 600, the prompt also includes “private” information that Sophia has not communicated to Sarah but that is necessary to accomplish the objective for the interaction: to maximize the valuation of the fruit possessed by Sophia at the end of the negotiation. Namely, the prompt identifies which fruits Sophia has and how much Sophia values each type of fruit.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, e.g., one or more modules of computer program instructions encoded on a tangible non transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a data communication network.

In this specification, the term “database” is used broadly to refer to any collection of data: the data does not need to be structured in any particular way, or structured at all, and it can be stored on storage devices in one or more locations. Thus, for example, the index database can include multiple collections of data, each of which may be organized and accessed differently.

Similarly, in this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, e.g., inference, workloads.

Machine learning models can be implemented and deployed using a machine learning framework, e.g., a TensorFlow framework or a Jax framework.

Embodiments of the subject matter described in this specification can be implemented in a computing system that includes a back end component, e.g., as a data server, or that includes a middleware component, e.g., an application server, or that includes a front end component, e.g., a client computer having a graphical user interface, a web browser, or an app through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

1. A method performed by one or more computers, the method comprising:
during an interaction between a plurality of actors:
identifying a first plurality of first strategies for selecting between first parameterizations for communications for a first actor of the plurality of actors for the interaction, wherein each first parameterization parametrizes a set of context variables for the communications of the first actor during the interaction;
identifying a second plurality of second strategies for selecting between second parameterizations for communications for a second actor of the plurality of actors for the interaction, wherein each second parameterization parametrizes a set of context variables for the communications of the second actor during the interaction;
for each of a plurality of pairs that each include a respective first strategy and a respective second strategy:
generating, using a language model neural network, one or more simulations of the interaction given that the first actor communicates in accordance with the first strategy and the second actor communicates in accordance with the second strategy;
determining, from the one or more simulations, a score for the pair that indicates a degree to which the first actor communicating in accordance with the first strategy and the second actor communicating in accordance with the second strategy satisfies one or more objectives for the interaction;
selecting, using the scores for the plurality of pairs, a first parametrization for the first actor; and
generating, by processing an input that conditions the language model neural network on the selected first parameterization, a suggested communication for the first actor.

2. The method of claim 1, wherein the first actor is a user of a user device, the method further comprising:
providing the suggested communication for presentation to the first user in a user interface of the user device.

3. The method of claim 1, wherein:
during the interaction, the communications generated by the first actor are natural language communications, and
the suggested communication is a suggested natural language communication.

4. The method of claim 3, wherein the first actor is a user of a user device, wherein, during the interaction, the first user receives communications from the second actor and transmits communications to the second actor through a user interface of the user device, and wherein the method further comprises:
providing the suggested natural language communication for presentation to the first user in the user interface of the user device.

5. The method of claim 4, further comprising:
receiving a user input selecting the suggested natural language communication; and
in response, transmitting the suggested natural language communication to the second actor.

6. The method of claim 1, wherein selecting, using the scores for the plurality of pairs, a first parameterization comprises:
applying a game theory solver to a representation of the interaction that comprises the scores for the plurality of pairs to identify an optimal first parameterization for the first user.

7. The method of claim 1, wherein generating, using a language model neural network, one or more simulations of the interaction comprises, for each simulation and at each of a plurality of iterations:
identifying previous communications between the first actor and the second actor during the simulation;
selecting the first actor or the second actor as a current actor for the iteration:
when the first actor is selected as the current actor,
selecting a first parametrization for the iteration in accordance with the first strategy;
processing, using the language model neural network, (i) an input that conditions the language model neural network on the selected first parameterization and (ii) at least some of the previous communications during the simulation to generate a communication for the first actor; and
when the second actor is selected as the current actor,
selecting a second parametrization for the iteration in accordance with the second strategy;
processing, using the language model neural network, (i) an input that conditions the language model neural network on the selected second parameterization and (ii) at least some of the previous communications during the simulation to generate a communication for the second actor.

8. The method of claim 1, wherein the set of context variables comprises one or more context variables defining a communication style for the communications.

9. The method of claim 1, wherein the set of context variables comprises one or more context variables defining a set of information that is available as context to the first actor or the second actor.

10. The method of claim 1, wherein one or more of the first strategies select a same first parameterization for each communication during the interaction.

11. The method of claim 1, wherein one or more of the first strategies select different first parameterizations for different communications during the interaction.

12. The method of claim 1, further comprising:
receiving a user input specifying a context variable; and
processing an input defining the context variable using the language model neural network to generate one or more possible values for the context variables that can be used to parameterize the context variable.

13. The method of claim 1, wherein determining, from the one or more simulations, a score for the pair that indicates a degree to which the first actor communicating in accordance with the first strategy and the second actor communicating in accordance with the second strategy satisfies an objective for the interaction comprises, for each of the one or more simulations:
generating a summary input from one or more of the communications generated during the simulation;
generating a criteria input characterizing the objective for the interaction; and
processing the summary input and the criteria input using a second language model neural network to generate an output that defines a simulation score for the simulation that indicates a degree to which the simulation satisfies the one or more criteria.

14. The method of claim 1, wherein determining, from the one or more simulations, a score for the pair that indicates a degree to which the first actor communicating in accordance with the first strategy and the second actor communicating in accordance with the second strategy satisfies an objective for the interaction comprises, for each of the one or more simulations:
processing an input comprising one or more of the communications generated during the simulation using a second language model neural network to generate a summary of the simulation; and
generating, from the summary, a simulation score for the simulation that indicates a degree to which the simulation satisfies the one or more criteria.

15. The method of claim 14, wherein generating, from the summary, a simulation score for the simulation that indicates a degree to which the simulation satisfies the one or more criteria comprises:
applying one or more heuristics to the summary to generate the simulation score.

16. The method of claim 14, wherein generating, from the summary, a simulation score for the simulation that indicates a degree to which the simulation satisfies the one or more criteria comprises:
generating a criteria input characterizing the objective for the interaction; and
processing the summary input and the criteria input using the second language model neural network to generate an output that defines the simulation score.

17. The method of claim 13, wherein the second language model neural network is the language model neural network.

18. The method of claim 1, wherein the input that conditions the language model neural network on the selected first parameterization comprises private information characterizing an objective of the first actor for the interaction.

19. One or more computer-readable storage media storing instructions that when executed by one or more computers cause the one or more computers to perform operations comprising:
during an interaction between a plurality of actors:
identifying a first plurality of first strategies for selecting between first parameterizations for communications for a first actor of the plurality of actors for the interaction, wherein each first parameterization parametrizes a set of context variables for the communications of the first actor during the interaction;
identifying a second plurality of second strategies for selecting between second parameterizations for communications for a second actor of the plurality of actors for the interaction, wherein each second parameterization parametrizes a set of context variables for the communications of the second actor during the interaction;
for each of a plurality of pairs that each include a respective first strategy and a respective second strategy:
generating, using a language model neural network, one or more simulations of the interaction given that the first actor communicates in accordance with the first strategy and the second actor communicates in accordance with the second strategy;
determining, from the one or more simulations, a score for the pair that indicates a degree to which the first actor communicating in accordance with the first strategy and the second actor communicating in accordance with the second strategy satisfies one or more objectives for the interaction;
selecting, using the scores for the plurality of pairs, a first parametrization for the first actor; and
generating, by processing an input that conditions the language model neural network on the selected first parameterization, a suggested communication for the first actor.

20. A system comprising:
one or more computers; and
one or more storage devices storing instructions that, when executed by the one or more computers, cause the one or more computers to perform operations comprising:
during an interaction between a plurality of actors:
identifying a first plurality of first strategies for selecting between first parameterizations for communications for a first actor of the plurality of actors for the interaction, wherein each first parameterization parametrizes a set of context variables for the communications of the first actor during the interaction;
identifying a second plurality of second strategies for selecting between second parameterizations for communications for a second actor of the plurality of actors for the interaction, wherein each second parameterization parametrizes a set of context variables for the communications of the second actor during the interaction;
for each of a plurality of pairs that each include a respective first strategy and a respective second strategy:
generating, using a language model neural network, one or more simulations of the interaction given that the first actor communicates in accordance with the first strategy and the second actor communicates in accordance with the second strategy;
determining, from the one or more simulations, a score for the pair that indicates a degree to which the first actor communicating in accordance with the first strategy and the second actor communicating in accordance with the second strategy satisfies one or more objectives for the interaction;
selecting, using the scores for the plurality of pairs, a first parametrization for the first actor; and
generating, by processing an input that conditions the language model neural network on the selected first parameterization, a suggested communication for the first actor.
